(19) United States
(12) Patent Application Publication
(10) Pub. No.: US 2023/0284475 A1
(43) Pub. Date: Sep. 7, 2023

(54) DISPLAY DEVICE

(71) Applicant: Samsung Display Co., Ltd., Yongin-Si (KR)

(72) Inventors: Eon Seok OH, Seongnam-si (KR); Jung Joon SEO, Yongin-si (KR); Tae Hyun SUNG, Uiwang-si (KR); Seung Soo HONG, Bucheon-si (KR); Je-Hyun SONG, Asan-si (KR)

(21) Appl. No.: 17/964,844

(22) Filed: Oct. 12, 2022

(30) Foreign Application Priority Data
Mar. 4, 2022 (KR) 10-2022-0028372

(51) Int. Cl. H01L 51/52; H01L 27/32

(52) U.S. Cl. CPC H01L 51/5253; H01L 27/3234; H01L 27/326; H01L 51/5265

(57) ABSTRACT

A display device comprises a substrate, a pixel electrode, a common electrode, an intermediate layer, a semiconductor layer, a metal layer, and an organic layer. The substrate includes an opening area, a peripheral area surrounding the opening area, and a display area surrounding the peripheral area. The pixel electrode overlaps the display area. The common electrode overlaps the pixel electrode. The intermediate layer is disposed between the pixel electrode and the common electrode and includes a light emitting layer and a functional layer. The semiconductor layer overlaps the peripheral area and is spaced from the display area. The metal layer overlaps the semiconductor layer. The organic layer is disposed between the semiconductor layer and the metal layer. The common electrode, the functional layer, and the metal layer respectively have a first opening, a second opening, a third opening overlapping each other and overlapping the semiconductor layer.

### CROSS-REFERENCE TO RELATED APPLICATION

This application claims priority to and the benefit of Korean Patent Application No. 10-2022-0028372 filed in the Korean Intellectual Property Office on Mar. 04, 2022; the Korean Patent Application is incorporated by reference.

### BACKGROUND

### (A) Technical Field

This technical field relates to a display device.

### (B) Description of the Related Art

An electronic device, such as a smartphone, a tablet computer, or a laptop computer, may include a camera in addition to a display device that displays an image. The camera may or may not overlap the display device.

The Background section is for enhancement of understanding of the background of the application. The Background section may contain information that does not form the prior art that is already known in this country to a person of ordinary skill in the art.

### SUMMARY

Embodiments are related to a display device including an opening area in a display area. The opening area may include a through hole in a substrate.

A display device according to an embodiment comprises a substrate including an opening area, a peripheral area surrounding the opening area, and a display area surrounding the peripheral area. The display device further comprises a pixel electrode disposed in the display area, a common electrode disposed over the pixel electrode, an intermediate layer disposed between the pixel electrode and the common electrode and including a light emitting layer and a functional layer, a semiconductor layer disposed in the peripheral area, a metal layer disposed on the semiconductor layer, and an organic layer disposed between the semiconductor layer and the metal layer. The common electrode and the functional layer are disposed in the display area and the peripheral area, and the common electrode, the functional layer, and the metal layer have an opening overlapping the semiconductor layer.

The display device may further include an encapsulation layer disposed over the common electrode and including an inorganic layer. The inorganic layer may be in contact with the organic layer through the opening.

The display device may further include a capping layer disposed between the common electrode and the encapsulation layer. The capping layer may have an opening overlapping the opening.

The opening may surround the opening area.

The opening may be ring-shaped.

The metal layer may cover a side surface of the organic layer.

The display device may further include a buffer layer disposed between the substrate and the semiconductor layer. The metal layer may be in contact with the buffer layer.

The metal layer may be formed of a same material as the pixel electrode in a same process.

The organic layer may have a thickness of about 1 µm to about 7 µm.

The display device may further include a first organic insulating layer, a second organic insulating layer, a pixel defining layer, and a spacer sequentially stacked on the substrate in the display area. The organic layer may include a layer formed of a same material in a same process as at least one of the first organic insulating layer, the second organic insulating layer, the pixel defining layer, and the spacer.

The organic layer may include a first organic layer and a second organic layer disposed over the first organic layer.

The display device may further include an inorganic layer disposed between the semiconductor layer and the organic layer.

A through hole passing through at least the substrate may be formed in the opening area.

The functional layer may include at least one of a hole injection layer, a hole transport layer, an electron transport layer, and an electron injection layer.

The display device may further include a dam disposed in the peripheral area and surrounding the opening area,

The opening may be disposed between the display area and the dam, or between the dam and the opening area.

display device according to and embodiment comprises: a substrate that includes a display area, an opening area including a through hole, and a peripheral area disposed between the display area and the through hole; a light emitting diode disposed in the display area and including a pixel electrode, an intermediate layer, and a common electrode; and a cut structure disposed in the peripheral area and including a high refractive index layer, a low refractive index layer, and a reflective layer. The intermediate layer and the common electrode are disposed in the display area and the peripheral area, and the intermediate layer and the common electrode have an opening overlapping the cut structure.

The opening may surround the through hole.

The intermediate layer may include a light emitting layer and a functional layer, and the functional layer may include at least one of a hole injection layer, a hole transport layer, an electron transport layer, and an electron injection layer. The functional layer of the intermediate layer may be disposed in the peripheral area.

The display device may further include an encapsulation layer covering the light emitting diode and including an inorganic layer. The inorganic layer may be in contact with the low refractive index layer through the opening.

The low refractive index layer may cover at least an upper surface of the high refractive index layer, and the reflective layer may cover a side surface of the low refractive index layer.

An embodiment may be related to a display device. The display device may include a substrate, a pixel electrode, a common electrode, an intermediate layer, a semiconductor layer, a metal layer, and an organic layer. The substrate may include an opening area, a peripheral area surrounding the opening area, and a display area surrounding the peripheral area. The pixel electrode may overlap the display area. The common electrode may overlap the pixel electrode. The intermediate layer may be disposed between the pixel electrode and the common electrode and may include a light emitting layer and a functional layer. The semiconductor layer may overlap the peripheral area and may be spaced from the display area. The metal layer may overlap the semiconductor layer. The organic layer may be disposed between the semiconductor layer and the metal layer. The common electrode, the functional layer, and the metal layer may respectively have a first opening, a second opening, a third opening overlapping each other and overlapping the semiconductor layer.

The display device may include an encapsulation layer overlapping the common electrode and including an inorganic layer. The inorganic layer may directly contact the organic layer through the first opening, the second opening, and the third opening.

The display device may include a capping layer disposed between the common electrode and the encapsulation layer. The capping layer may have a fourth opening overlapping at least one of the first opening, the second opening, and the third opening.

At least one of the first opening, the second opening, and the third opening may surround the opening area.

The third opening may be ring-shaped.

The metal layer covers a side surface of the organic layer.

The display device may include a buffer layer disposed between the substrate and the semiconductor layer. The metal layer may directly contact the buffer layer.

A material of the metal layer may be identical to a material of the pixel electrode.

Thicknesses of the organic layer may be in a range of 1 µm to 7 µm.

The display device may include a first organic insulating layer, a second organic insulating layer, a pixel defining layer, and a spacer sequentially stacked on the display area. The organic layer may include a layer formed of a same material as at least one of the first organic insulating layer, the second organic insulating layer, the pixel defining layer, and the spacer.

The organic layer may include a first organic layer and a second organic layer overlapping the first organic layer.

The display device may include an inorganic layer disposed between the semiconductor layer and the organic layer.

The substrate may include a through hole passing through the opening area.

The functional layer may include at least one of a hole injection layer, a hole transport layer, an electron transport layer, and an electron injection layer.

The display device may include a dam overlapping the peripheral area and surrounding the opening area. The third opening may be disposed between the display area and the dam or disposed between the dam and the opening area.

An embodiment may be related to a display device. The display device may include the following elements: a substrate that includes a display area, an opening area including a through hole, and a peripheral area between the display area and the through hole; a light emitting diode overlapping the display area and including a pixel electrode, a portion of an intermediate layer, and a portion of a common electrode; and a cut structure overlapping the peripheral area, spaced from the display area, and including a first refractive layer, a second refractive layer, and a reflective layer. A refractive index of the first refractive layer may be higher than a refractive index of the second refractive area. The intermediate layer and the common electrode respectively have a first opening and a second opening overlapping each other and overlapping the cut structure.

At least one of the first opening and the second opening may surround the through hole.

The intermediate layer may include a light emitting layer and a functional layer. The functional layer may include at least one of a hole injection layer, a hole transport layer, an electron transport layer, and an electron injection layer. The functional layer may overlap the peripheral area.

The display device may include an encapsulation layer covering the light emitting diode and including an inorganic layer. The inorganic layer may directly contact the second refractive layer through the first opening and the second opening.

The second refractive layer may overlap the first refractive layer. The first refractive layer may be disposed between the second refractive layer and the substrate. The reflective layer may cover a side surface of the second refractive layer.

According to embodiments, in a display device, penetration of moisture through an opening area may be advantageously prevented or minimized.

### BRIEF DESCRIPTION OF THE DRAWINGS

FIG. 1 illustrates a schematic exploded perspective view of a display device according to an embodiment.

FIG. 2 illustrates a schematic top plan view of a display panel according to an embodiment.

FIG. 3 illustrates a schematic top plan view of area “A” indicated in FIG. 1 and/or FIG. 2 according to an embodiment.

FIG. 4 illustrates a circuit diagram of one pixel of a display device according to an embodiment.

FIG. 5 illustrates a cross-sectional view of a display area in a display panel according to an embodiment.

FIG. 6 illustrates a cross-sectional view of a display area and a peripheral area in a display panel according to an embodiment.

FIG. 7 illustrates a cross-sectional view of a cut portion (or cut structure) in a display panel according to an embodiment.

FIG. 8 illustrates a schematic view of a resonant structure according to an embodiment.

FIG. 9 illustrates a photographed view of a processed cross-section of a pixel conductive layer using a resonant structure according to an embodiment.

FIG. 10 illustrates a graph of laser energy amplification simulation results according to presence or absence of a semiconductor layer, a refractive index of an organic layer, and a thickness of the organic layer.

Each of FIG. 11, FIG. 12, FIG. 13, FIG. 14, and FIG. 15 illustrates a cross-sectional view of a peripheral area in a display panel according to an embodiment.

### DETAILED DESCRIPTION

Examples of embodiments are described with reference to the accompanying drawings.

Although the terms “first,” “second,” etc. may be used to describe various elements, these elements should not be limited by these terms. These terms may be used to distinguish one element from another element. A first element may be termed a second element without departing from teachings of one or more embodiments. The description of an element as a “first” element may not require or imply the presence of a second element or other elements. The terms “first,” “second,” etc. may be used to differentiate different categories or sets of elements. For conciseness, the terms “first,” “second,” etc. may represent “first-category (or first-set),” “second-category (or second-set),” etc., respectively.

The term “on” may mean “directly on” or “indirectly on.” The term “connect” may mean “directly connect” or “indirectly connect.” The term “connect” may mean “mechanically connect” and/or “electrically connect.” The term “connected” may mean “electrically connected” or “electrically connected through no intervening transistor.” The term “insulate” may mean “electrically insulate” or “electrically isolate.” The term “conductive” may mean “electrically conductive.” The term “drive” may mean “operate” or “control.” The term “include” may mean “be made of.” The term “adjacent” may mean “immediately adjacent.” The expression that an element extends in a particular direction may mean that the element extends lengthwise in the particular direction and/or that the lengthwise direction of the element is in the particular direction. The term “pattern” may mean “member.” The term “portion” may mean “structure.” The term “define” may mean “form” or “provide.” The expression that a space or opening overlaps an object may mean that (the position of) the space or opening overlaps with (the position of) the object. The term “overlap” may be equivalent to “be overlapped by.” The expression that a first element overlaps with a second element in a plan view may mean that the first element overlaps the second element in direction perpendicular to a substrate. The expression that an element is disposed in a particular area of a substrate may mean that the element overlaps and/or is disposed on the particular area of the substrate and/or may mean that the element is disposed in an area of a display panel that corresponds to the particular area of the substrate. The term “cut” or “cut-off” may mean “interruption” or “obstruction.”

Unless explicitly described to the contrary, the word “comprise/include” and variations such as “comprises/ includes” or “comprising/including” may indicate the inclusion of stated elements but may not indicate the exclusion of any other elements.

In the drawings, signs x, y, and z are/indicate different directions: x is/indicates a first direction, y is/indicates a second direction perpendicular to and/or different from the first direction, and z is/indicates a third direction perpendicular to and/or different from the first and second directions.

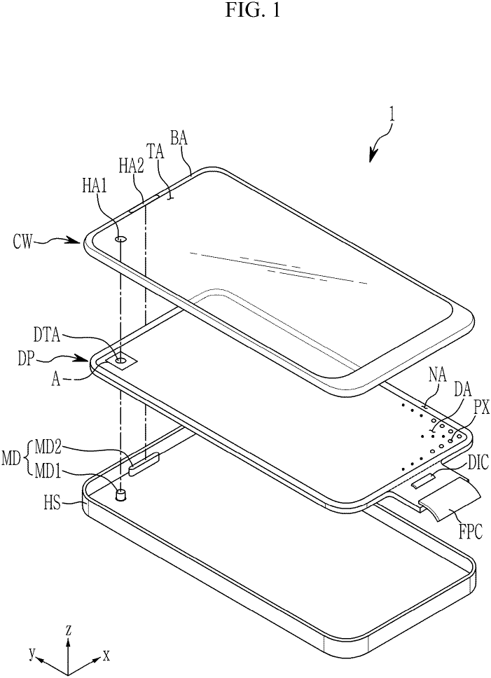

FIG. 1 illustrates a schematic exploded perspective view of a display device 1 according to an embodiment.

The display device 1 (or simply referred to as a display device) may be included in an electronic device, such as a smart phone, a mobile phone, a tablet computer, a multimedia player, a laptop computer, or a game machine. The display device 1 may be rigid. The display device 1 may include a flexible portion capable of bending, folding, and/or rolling. The display device 1 may display an image in a third direction z and on a front surface in a plane defined by a first direction x and a second direction y. The display device 1 may include a display panel DP, a cover window CW, an electronic module MD, and a housing HS.

The display panel DP may include a display area DA and a non-display area NA. The display area DA is an area in which an image is displayed in response to input signals, and may correspond to a screen. The non-display area NA is an area in which no image is displayed in response to input signals, and may surround at least a portion of the display area DA.

The display panel DP may include pixels PX arranged in the display area DA, and an image may be displayed by a combination of light emitted by the pixels PX. The display panel DP may include pixel circuits and signal lines for driving the pixels PX. The display panel DP may be a light emitting display panel including light emitting diodes, and a light emitting diode may be included in each pixel PX. The display panel DP may include a touch sensor layer capable of sensing a touch.

The display panel DP may include an opening area DTA. The opening area DTA may be positioned in and/or surrounded by the display area DA. The opening area DTA may include a through hole (or through opening) that passes through the display panel DP. Some of the pixels PX may surround the opening area DTA. Although the opening area DTA is illustrated as being positioned at an upper left side of the display panel DP, a position of the opening area DTA may be different in different embodiments.

The non-display area NA of the display panel DP may include and/or support a driving part that generates and/or processes various signals for driving the pixels PX. For example, the driving part may include a data driver DIC that applies a data voltage to the pixels PX, a gate driver that applies a gate signal to the pixels PX, and a controller that controls the data driver DIC and the gate driver. The gate driver may be integrated in the non-display area NA. The data driver DIC is provided in a form of an integrated circuit chip and is mounted on the non-display area NA. The data driver DIC and/or the controller may be disposed on a flexible printed circuit film FPC to be electrically connected to the display panel DP.

The cover window CW may be positioned on the display panel DP to protect the display panel DP from an external impact, and to transmit an image displayed on the display panel DP. The cover window CW may be attached to the display panel DP by an adhesive such as an optically clear adhesive (OCA) or an optically clear resin (OCR). The cover window CW may be coated on the display panel DP. The cover window CW may include a transmission area TA and a blocking area BA. The transmission area TA may be an optically transparent area, and may transmit incident light. The blocking area BA may have lower light transmittance than the transmission area TA. The blocking area BA may define a shape of the transmission area TA. The blocking area BA may surround the transmission area TA. The blocking area BA may display a predetermined color. The blocking area BA overlaps the non-display area NA of the display panel DP to block the non-display area NA from being visible.

The cover window CW may include a first hole area HA1 and a second hole area HA2. Each of the first hole area HA1 and the second hole area HA2 may overlap the electronic module MD. The electronic module MD may operate by receiving external signals provided through the first hole area HA1 and/or the second hole area HA2.

The first hole area HA1 may be positioned in the transmission area TA, and the second hole area HA2 may be positioned in the blocking area BA. The first hole area HA1 and the second hole area HA2 may be positioned in opposite areas, or both of them may be positioned in the transmission area TA or the blocking area BA. The number of the hole areas may be different for different embodiments. The first hole area HA1 may have a circular shape, and the second hole area HA2 may extend in the first direction x. The shapes and sizes of hole areas may be different for different embodiments.

In each of the first hole area HA1 and the second hole area HA2, a predetermined depression recessed from a rear surface of the cover window CW may be defined. The depth of the depression may be less than a thickness of the cover window CW. The first hole area HA1 may overlap the opening area DTA of the display panel DP.

The electronic module MD may include functional modules related to the operation of the display device 1. The electronic module MD may be electrically connected to the display panel DP through a connector. The electronic module MD may include a camera, a sensor, a speaker, and/or a microphone. The electronic module MD may include a first electronic module MD1 and a second electronic module MD2.

The first electronic module MD1 may receive an external input transmitted through the opening area DTA and the first hole area HA1, and/or may provide an output through the opening area DTA and the first hole area HA1. The first electronic module MD1 may be a light emitting module, a light sensing module, and/or a photographing module. For example, the first electronic module MD1 may include at least one of a camera module for photographing a subject, a light emitting module for outputting infrared rays, and a CMOS sensor for detecting infrared rays.

The second electronic module MD2 may collect a sound signal such as voice through the second hole area HA2, and/or may provide a sound signal such as processed voice to the outside. For example, the second electronic module MD2 may include at least one of a sound input module and a sound output module. The sound input module may include a microphone capable of receiving a sound signal. The sound output module may include a speaker that outputs sound data as a sound signal.

The electronic module MD may be a single module, may include more than two electronic modules, and/or may include modules disposed at different locations.

The housing HS may be combined with the cover window CW to form an appearance of the display device 1. The housing HS may be made of a material with high rigidity, such as metal, glass, or plastic. The display panel DP and the electronic module MD may be positioned in an inner space of the display device 1 defined by the cover window CW and the housing HS.

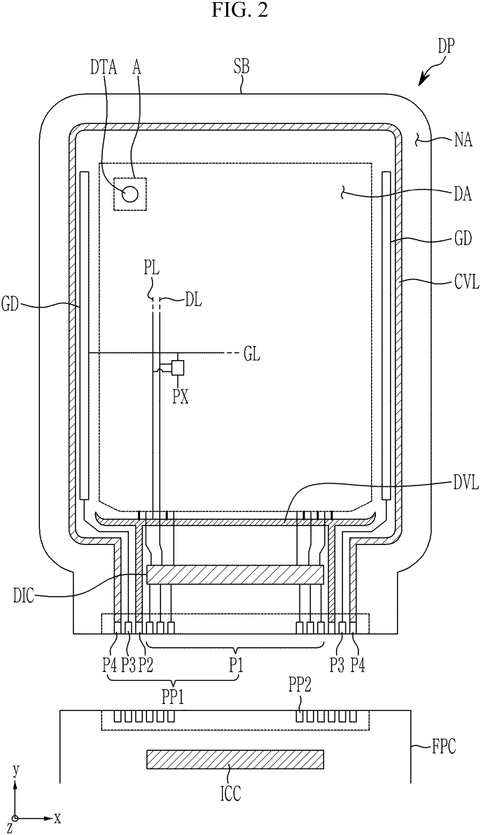

FIG. 2 illustrates a schematic top plan view of a display panel according to an embodiment.

Referring to FIG. 2, the display panel DP may include a substrate SB, and the substrate SB may include areas corresponding to the areas of the display panel DP, including the opening area DTA, the display area DA, and the non-display area NA. The opening area DTA may be positioned within and/or surrounded by the display area DA.

The display panel DP may include the pixels PX, and the pixels PX may be disposed in the display area DA (and may overlap the display area of the substrate SB). Each pixel PX may include a light emitting diode and a pixel circuit connected to the light emitting diode. The pixel PX may emit red, green, blue, or white light.

The display panel DP may include signal lines, a gate driver GD, and a pad part PP1. The signal lines may include gate lines GL, data lines DL, driving voltage lines PL, a driving voltage transmitting line DVL, and a common voltage transmitting line CVL. The gate lines GL may extend across the display area DA in the first direction x. The data lines DL and the driving voltage lines PL may extend across the display area DA in the second direction y. The driving voltage transmitting line DVL may be disposed in the non-display area NA. The driving voltage transmitting line DVL may be connected to the driving voltage lines PL, and may transmit a driving voltage EL_{VDD}. The common voltage transmitting line CVL may be disposed in the non-display area NA. The common voltage transmitting line CVL may surround the display area DA. The common voltage transmitting line CVL may transmit a common voltage ELvss to an electrode of the light emitting diode of each pixel PX.

The gate driver GD may be positioned at two sides of the display area DA opposite in the first direction x. The gate driver GD may provide a gate signal to the pixel PX through a gate line GL. The pad part PP1 may be disposed at one end of the display panel DP.

The pad part PP1 may include terminals P1, P2, P3, and P4 that may be arranged along the first direction x. The terminals P1, P2, P3, and P4 may be electrically connected to terminals of a pad part PP2 of the flexible printed circuit film FPC. The flexible printed circuit film FPC may transmit a signal or power of a controller ICC to the display panel DP through the pad parts PP1 and PP2.

The controller ICC may convert an image signal inputted from an external source into an image data signal and may provide the image data signal to the data driver DIC through the terminals P1. The controller ICC may receive a vertical synchronization signal, a horizontal synchronization signal, and a clock signal, may generate control signals for controlling driving of the gate driver GD and the data driver DIC, and may provide the control signals through the terminals P3 and P1. The controller ICC may supply a driving voltage to the driving voltage transmitting line DVL through the terminal P2. The controller ICC may supply the common voltage EL_{VSS} to the common voltage transmitting line CVL through the terminal P4. The data driver DIC may be positioned in the non-display area NA. For example, the data driver DIC may be disposed between the display area DA and the pad part PP1. The data driver DIC may be connected to the data lines DL, and may provide data voltages V_{DAT} to the pixel PX through the data lines DL.

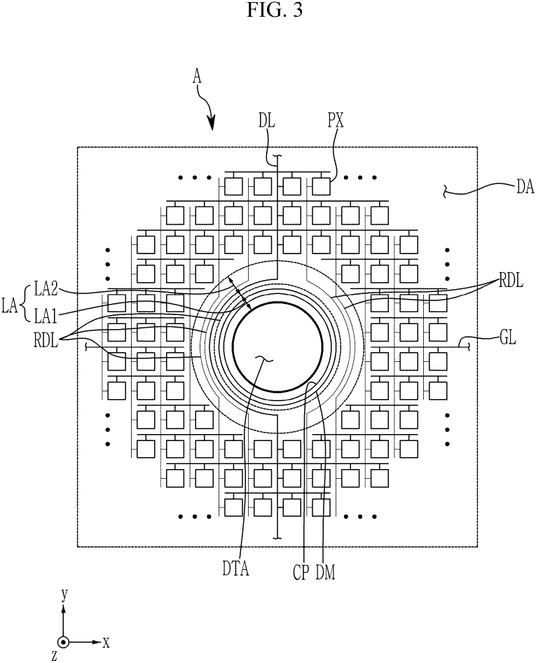

FIG. 3 illustrates a schematic top plan view of area “A” indicated in FIG. 1 and/or FIG. 2 according to an embodiment.

Referring to FIG. 3, the display panel DP may include the opening area DTA and a peripheral area LA surrounding the opening area DTA. The opening area DTA and the peripheral area LA may be surrounded by the display area DA. The peripheral area LA may be an intermediate area positioned between the opening area DTA and the display area DA. The peripheral area LA may have a substantially donut shape. The peripheral area LA may include a first peripheral area LA1 and a second peripheral area LA2. The first peripheral area LA1 may be closer to the opening area DTA than the second peripheral area LA2; the second peripheral area LA2 may be closer to the display area DA than the first peripheral area LA1. Among circles shown by dotted lines in FIG. 3, a dashed circle adjacent to the opening area DTA indicates a boundary between the first peripheral area LA1 and the second peripheral area LA2, and another dashed circle indicates a boundary between the peripheral area LA and the display area DA (i.e., a boundary between the second peripheral area LA2 and the display area DA).

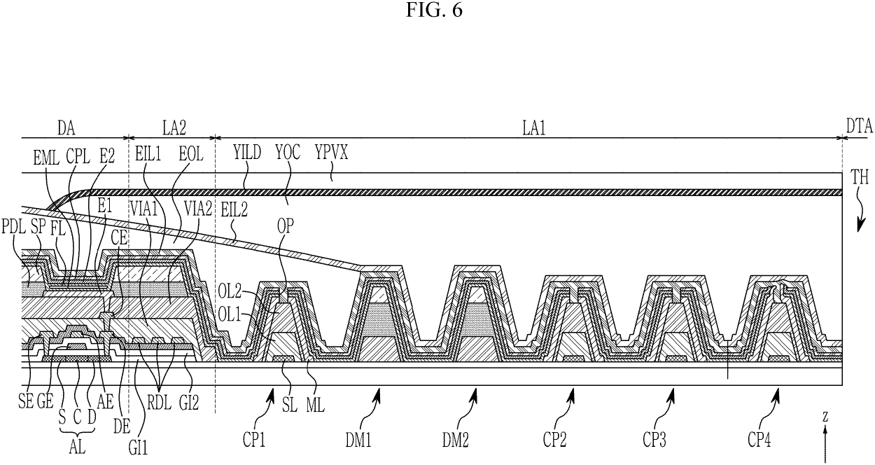

The first peripheral area LA1 may be a buffer area that prevents damage to the signal lines GL and DL during laser irradiation to form the opening area DTA. A dam DM may be positioned in the first peripheral area LA1. The dam DM may surround the opening area DTA. The dam DM may have a ring shape. Although one dam DM is shown, a plurality of dams DM may be provided, and each dam DM may surround the opening area DTA. A cut portion CP (or cut structure CP) may be positioned in the first peripheral area LA1. The cut portion CP may surround the opening area DTA. The cut portion CP may have a substantially ring shape. Although one cut portion CP is illustrated, a plurality of cut portions CP (e.g., CP1, CP2, CP3, and CP4 illustrated in FIG. 6) may be provided, and each cut portion CP may surround the opening area DTA. Although the cut portion CP is illustrated as being positioned between the opening area DTA and the dam DM, the cut portion CP may be positioned between the dam DM and the second peripheral area LA2. An opening OP (illustrated in FIG. 6) may overlap the cut portion CP (e.g., CP1 illustrated in FIG. 1), may surround the opening area DA, and may have a ring shape.

The second peripheral area LA2 may accommodate a bypass portion RDL, i.e., a portion of a data line DL extending along a periphery of the opening area DTA. The bypass portion RDL may have a substantially semicircular shape. Pixels PX positioned at opposite sides of the opening area DTA opposite in the second direction y may be connected to the bypass portion RDL of a same data line DL.

Gate lines GL may or may not be positioned in the second peripheral area LA2. Two separate gate lines GL may be connected to the pixels PX positioned at opposite sides of the opening area DTA opposite in the first direction x. A gate line GL may include a bypass portion extending along the periphery of the opening area DTA in the second peripheral area LA2.

In addition to the data line DL and the gate line GL are illustrated in FIG. 3, the pixel PX may be connected to other signal lines, such as a driving voltage line and an initialization voltage line. One or more gate lines GL may be connected to one pixel PX.

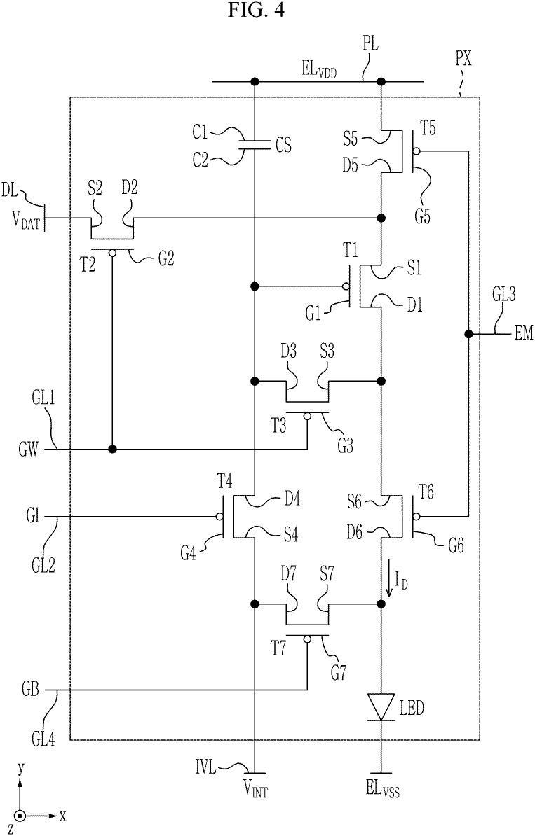

FIG. 4 illustrates a circuit diagram of one pixel of a display device according to an embodiment.

Referring to FIG. 4, the pixel PX may include transistors T1 to T7, a storage capacitor CS, and a light emitting diode LED that are connected to signal lines GL1, GL2, GL3, GL4, DL, PL, and IVL.

The transistors T1 to T7 may include a driving transistor T1, a switching transistor T2, a compensation transistor T3, an initialization transistor T4, an operation control transistor T5, a light emitting control transistor T6, and a bypass transistor T7.

The signal lines GL1, GL2, GL3, GL4, DL, PL, and IVL may include a scan line GL1, an initialization control line GL2, a light emitting control line GL3, a bypass control line GL4, a data line DL, a driving voltage line PL, and an initialization voltage line IVL. The wire schematically illustrated as the gate line GL in FIG. 2 and FIG. 3 may be divided into the scan line GL1, the initialization control line GL2, the light emitting control line GL3, and the bypass control line GL4.

The scan line GL1 may transmit a scan signal GW to the switching transistor T2 and the compensation transistor T3. The initialization control line GL2 may transmit an initialization control signal GI to the initialization transistor T4. The light emitting control line GL3 may transmit a light emitting control signal EM to the operation control transistor T5 and the light emitting control transistor T6. The bypass control line GL4 may transmit a bypass signal GB to the bypass transistor T7. The bypass control line GL4 may be connected to the initialization control line GL2.

The data line DL may receive a data voltage V_{DAT}, and the driving voltage line PL and the initialization voltage line IVL may receive a driving voltage EL_{VDD} and an initialization voltage V_{INT}, respectively. The initialization voltage V_{INT} may initialize the driving transistor T1.

Transistors T1 to T7 may respectively include gate electrodes G1 to G7, first electrodes S1 to S7, and second electrodes D1 to D7, and the storage capacitor CS may include a first electrode C1 and a second electrode C2. The electrodes of the transistors T1 to T7 and the storage capacitor CS may be connected as shown in FIG. 4. An anode of the light emitting diode LED may be connected to the second electrode D1 of the driving transistor T1 through the light emitting control transistor T6, and may receive a driving current I_{D}. A cathode of the light emitting diode LED may receive the common voltage EL_{VSS}.

In the circuit structure of the pixel PX, the type of the transistors, the number of transistors, the number of the capacitor, and the connection between them may be different for different embodiments. For example, the compensation transistor T3, the initialization transistor T4, and/or the bypass transistor T7 may be N-type transistors.

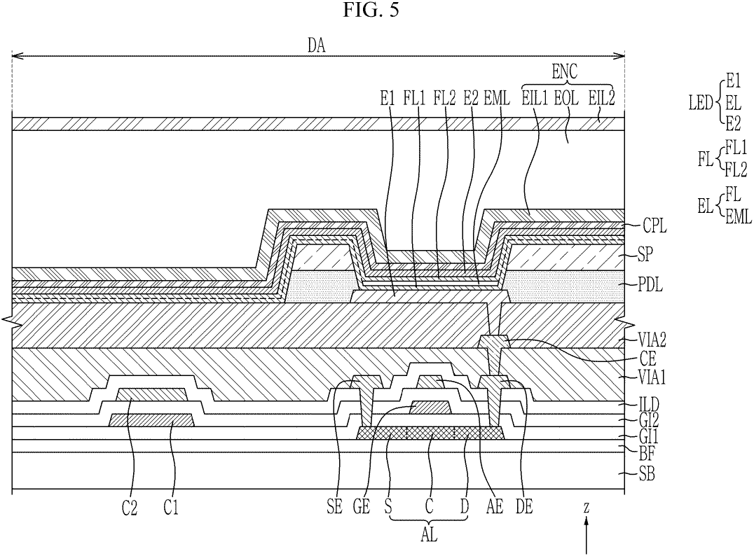

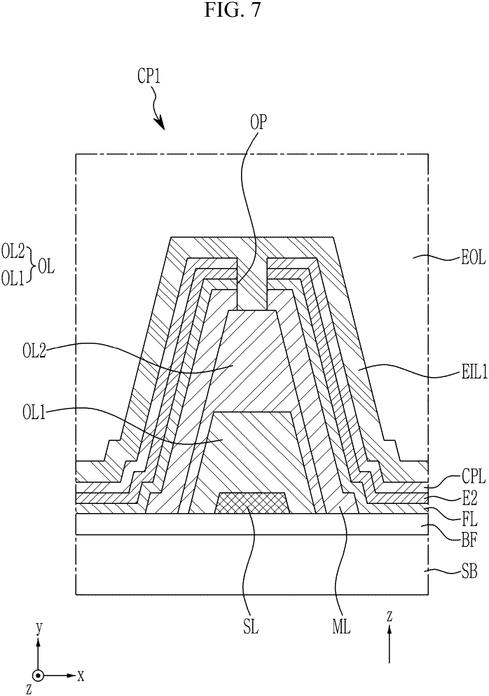

FIG. 5 illustrates a cross-section (stacked structure) corresponding to one pixel PX in the display area DA according to an embodiment. FIG. 6 illustrates a cross-section of the peripheral area LA, the display area DA, and the opening area DTA according to an embodiment. FIG. 7 is a cross-sectional view of a first cut portion CP1 illustrated in FIG. 6 according to an embodiment.

The display panel DP may include a substrate SB that includes areas corresponding to the display area DA and the peripheral area LA. The substrate SB may be a flexible substrate including a polymer resin such as polyimide, polyamide, or polyethylene terephthalate. The substrate SB may be multi-layered, and for example, may have a structure in which a base layer including a polymer resin and a barrier layer, which is an inorganic layer, are stacked. The substrate SB may be made of a material such as glass.

A buffer layer BF may be positioned on the substrate SB. The buffer layer BF may be positioned in the display area DA and the peripheral area LA. The buffer layer BF may block impurities from the substrate SB, thereby preventing deterioration of a semiconductor layer on the substrate SB, and may flatten a surface on the substrate SB to reduce stress of the semiconductor layer. The buffer layer BF may include an inorganic insulating material such as a silicon nitride (SiNₓ), a silicon oxide (SiOₓ), or a silicon oxynitride (SiOₓN_{y}), and may be a single layer or a multilayer structure. The buffer layer BF may include amorphous silicon (a-Si).

Some features and elements of the display area DA may be analogous to or identical to some features and elements of the peripheral area LA.

A semiconductor layer AL may be positioned on the buffer layer BF. The semiconductor layer AL may be referred to as an active layer. The semiconductor layer AL may include a first region S, a second region D, and a channel region C between the regions. The semiconductor layer AL may include one of amorphous silicon, polysilicon, and an oxide semiconductor. For example, the semiconductor layer AL may include a low temperature polycrystalline silicon (LTPS), or an oxide semiconductor material including at least one of zinc (Zn), indium (In), gallium (Ga), and tin (Sn). For example, the semiconductor layer AL may include an indium-gallium-zinc oxide (IGZO).

A first gate insulating layer GI1 may be disposed on the semiconductor layer AL. The first gate insulating layer GI1 may include an inorganic insulating material such as a silicon nitride, a silicon oxide, or a silicon oxynitride, and may be a single layer or a multilayer structure. The first gate insulating layer GI1 may be referred to as a first inorganic insulating layer.

A first gate conductive layer may include a gate electrode GE and a first electrode C1, and may be positioned on the first gate insulating layer GI1. Elements included in the first gate conductive layer may be formed of the same material in the same process. For example, the gate electrode GE and the first electrode C1 may be formed by depositing and patterning a conductive layer on the first gate insulating layer GI1. The gate electrode GE may overlap the channel region C of the semiconductor layer AL. A transistor may include the gate electrode GE and the semiconductor layer AL. The first gate conductive layer may include molybdenum (Mo), aluminum (Al), copper (Cu), and/or titanium (Ti), and may be a single layer or a multilayer structure.

A second gate insulating layer GI2 may be positioned on the first gate conductive layer. The second gate insulating layer GI2 may include an inorganic insulating material such as a silicon nitride, a silicon oxide, or a silicon oxynitride, and may be a single layer or a multilayer structure. The second gate insulating layer GI2 may be referred to as a second inorganic insulating layer.

A second gate conductive layer may include a second electrode C2 and an upper electrode AE, and may be positioned on the second gate insulating layer GI2. Elements included in the second gate conductive layer may be formed of the same material in the same process. The second electrode C2 may overlap the first electrode C1 to form the storage capacitor CS. The second electrode C2 and the upper electrode AE may be different portions of one conductive pattern. The second electrode C2 and the upper electrode AE may be electrically connected. The second gate conductive layer may include molybdenum (Mo), aluminum (Al), copper (Cu), and/or titanium (Ti), and may be a single layer or a multilayer structure.

An interlayer insulating layer ILD may be positioned on the second gate insulating layer GI2 and the second gate conductive layer. The interlayer insulating layer ILD may include an inorganic insulating material such as a silicon nitride, a silicon oxide, or a silicon oxynitride, and may be a single layer or a multilayer structure. The interlayer insulating layer ILD may be referred to as a third inorganic insulating layer.

A first data conductive layer may include a first electrode SE and a second electrode DE, and may be positioned on the interlayer insulating layer ILD. Elements included in the first data conductive layer may be formed of the same material in the same process. The first electrode SE and the second electrode DE may be respectively connected to the first region S and the second region D of the semiconductor layer AL through contact holes formed in the insulating layers GI1, GI2, and ILD. One of the first electrode SE and the second electrode DE may be a source electrode, and the other may be a drain electrode. The transistor may include the first electrode SE and/or the second electrode DE in addition to the gate electrode GE and the semiconductor layer AL. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or a multilayer structure. For example, the first data conductive layer may include a first layer including a refractory metal such as molybdenum, chromium, tantalum, and/or titanium, may include a second layer including a metal having low resistivity such as aluminum, copper, and/or silver, and may include an third layer including a refractory metal. For example, the third conductive layer may have a triple-layered structure such as titanium (Ti)-aluminum (Al)-titanium (Ti).

The first organic insulating layer VIA1 may be positioned on the first data conductive layer. The first organic insulating layer VIA1 may include an organic insulating material such as a general purpose polymer such as poly(methyl methacrylate) and polystyrene, a polymer derivative having a phenol-based group, an acryl-based polymer, an imide-based polymer (e.g., polyimide), or a siloxane-based polymer. The first organic insulating layer VIA1 may be referred to as a first planarization layer.

A second data conductive layer may include a connecting member CE and may be positioned on the first organic insulating layer VIA1. Elements included in the second data conductive layer may be formed of the same material in the same process. The connecting member CE may be connected to the second electrode DE of the transistor through a contact hole formed in the first organic insulating layer VIA1. The second data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or a multilayer structure. For example, the second data conductive layer may have a triple-layered structure such as titanium (Ti)-aluminum (Al)-titanium (Ti).

A second organic insulating layer VIA2 may be positioned on the second data conductive layer. The second organic insulating layer VIA2 may include an organic insulating material such as a general purpose polymer such as poly(methyl methacrylate) and polystyrene, a polymer derivative having a phenol-based group, an acryl-based polymer, an imide-based polymer, or a siloxane-based polymer. The second organic insulating layer VIA2 may be referred to as a second planarization layer.

A pixel conductive layer including a pixel electrode E1 may be positioned on the second organic insulating layer VIA2. Elements included in the pixel conductive layer may be formed of the same material in the same process. The pixel electrode E1 may be connected to the connecting member CE through a contact hole formed in the second organic insulating layer VIA2. Accordingly, the pixel electrode E1 may be electrically connected to the second electrode DE of the transistor to receive the driving current I_{D} for controlling the brightness of the light emitting diode LED. The transistor connected to the pixel electrode E1 may be the light emitting control transistor T6 connected to the driving transistor T1. The pixel conductive layer may be formed of a reflective conductive material or a semi-transmissive conductive material, or may be formed of a transparent conductive material. The pixel conductive layer may include a transparent conductive material such as an indium tin oxide (ITO) or an indium zinc oxide (IZO). The pixel conductive layer may include a metal such as lithium (Li), calcium (Ca), aluminum (Al), silver (Ag), magnesium (Mg), gold (Au), or a metal alloy of some of the metals. The pixel conductive layer may be multi-layered, and may have, for example, a triple-layered structure such as ITO-silver (Ag)-ITO.

A pixel defining layer PDL may be positioned on the second organic insulating layer VIA2, and a spacer SP may be positioned on the pixel defining layer PDL. The pixel defining layer PDL may have an opening overlapping and exposing the pixel electrode E1. The pixel defining layer PDL and the spacer SP may include an organic insulating material such as a general purpose polymer such as poly(methyl methacrylate) and polystyrene, a polymer derivative having a phenol-based group, an acryl-based polymer, an imide-based polymer, or a siloxane-based polymer. The pixel defining layer PDL and the spacer SP may be formed of the same material in the same process.

An intermediate layer EL may be positioned on the pixel defining layer PDL, the spacer SP, and the pixel electrode E1. The intermediate layer EL may include a light emitting layer EML and a functional layer FL. In the light emitting layer EML, electro-optical conversion is performed through combination of electrons and holes. The light emitting layer EML may include an organic material and/or an inorganic material that emits light of a predetermined color. The light emitting layer EML may be positioned in an opening of the pixel defining layer PDL, and may overlap the pixel electrode E1. The functional layer FL may include at least one of a hole injection layer, a hole transport layer, an electron transport layer, and an electron injection layer. The functional layer FL may include a first functional layer FL1 positioned between the pixel electrode E1 and the light emitting layer EML and may include a second functional layer FL2 positioned between the light emitting layer EML and a common electrode E2. The functional layer FL may be positioned inside and outside the opening. The functional layer FL may span the entire display area DA.

The common electrode E2 may be positioned on the intermediate layer EL. The common electrode E2, the pixel electrode E1, and the intermediate layer EL may form the light emitting diode LED, such as an organic light emitting diode or an inorganic light emitting diode. The pixel electrode E1 may be an anode of the light emitting diode LED, and the common electrode E2 may be a cathode of the light emitting diode LED. The common electrode E2 may have light transmittance and may be a thin layer of a metal or a metal alloy having a low work function such as calcium (Ca), barium (Ba), magnesium (Mg), aluminum (Al), and/or silver (Ag),. The common electrode E2 may include a transparent conductive oxide such as an indium tin oxide (ITO) or an indium zinc oxide (IZO). The common voltage EL_{VDD} may be applied to the common electrode E2.

A capping layer CPL may be positioned on the common electrode E2. The capping layer CPL may improve light efficiency through refractive index adjustment. The capping layer CPL may entirely cover the common electrode E2. The capping layer CPL may include an organic insulating material or an inorganic insulating material.

An encapsulation layer ENC may be positioned on the capping layer CPL. The encapsulation layer ENC may encapsulate the light emitting diode LED to prevent external moisture or oxygen from damaging the light emitting diode LED. The encapsulation layer ENC may entirely cover the display area DA. The encapsulation layer ENC may be a thin film encapsulation layer including one or more inorganic layers and one or more organic layers. For example, the encapsulation layer ENC may have a triple-layered structure of a first inorganic layer EIL1, an organic layer EOL, and a second inorganic layer EIL2. The first inorganic layer EIL1 may cover the common electrode E2, and may prevent moisture or oxygen from penetrating into the light emitting diode LED. The organic layer EOL may be disposed between the first inorganic layer EIL1 and the second inorganic layer EIL2, and may reduce stress between associated layers. The second inorganic layer EIL2 may cover the organic layer EOL. The second inorganic layer EIL2 may prevent moisture from being discharged from the organic layer EOL. The first inorganic layer EIL1 and the second inorganic layer EIL2 may include an inorganic insulating material such as a silicon oxide, a silicon nitride, or a silicon oxynitride, and may be formed by a deposition process. The organic layer EOL may be formed through a solution process such as a spin coating, slit coating, or inkjet process.

A touch sensor layer (not shown) including touch electrodes may be positioned on the encapsulation layer ENC. The touch electrodes may have a mesh structure having an opening overlapping the light emitting diode LED. An anti-reflective layer (not shown) for reducing reflection of external light may be positioned on the touch sensor layer.

FIG. 6 illustrates a cross-sectional structure of the peripheral area LA, the opening area DTA, and the display area DA. A through-hole TH passing through the display panel DP in the third direction z may be formed in the opening area DTA. The peripheral area LA may include a first peripheral area LA1 and a second peripheral area LA2.

The second peripheral area LA2 adjacent to the display area DA may be substantially the same as the display area DA in a stacked structure of insulating layers. Specifically, the buffer layer BF, the first gate insulating layer GI1, the second gate insulating layer GI2, the interlayer insulating layer ILD, the first organic insulating layer VIA1, the second organic insulating layer VIA2, the pixel defining layer PDL, and the spacer SP may be sequentially positioned on the substrate SB,. The first organic insulating layer VIA1 may cover side surfaces of the first gate insulating layer GI1, the second gate insulating layer GI2, and the interlayer insulating layer ILD. The second organic insulating layer VIA2 may cover a side surface of the first organic insulating layer VIA1. The bypass portions RDL may be positioned on the interlayer insulating layer ILD. The functional layer FL, the common electrode E2, the capping layer CPL, and the encapsulation layer ENC may be positioned in the second peripheral area LA2 may continuously extend to the display area DA. An overcoat layer YOC, an inorganic insulating layer YILD, and a passivation layer YPVX may be further positioned on the encapsulation layer ENC. The overcoat layer YOC, the inorganic insulating layer YILD, and the passivation layer YPVX may also be positioned in the display area DA and the first peripheral area LA1, and a touch sensor layer may be positioned between the encapsulation layer ENC and the passivation layer YPVX in the display area DA. Some of the overcoat layer YOC, the inorganic insulating layer YILD, and the passivation layer YPVX may be optional.

The substrate SB and the buffer layer BF may be positioned in the first peripheral area LA1. The substrate SB and the buffer layer BF may continuously span the display area DA, the second peripheral area LA2, and the first peripheral area LA1. The functional layer FL, the common electrode E2, and the capping layer CPL may be formed by an evaporation deposition process, and it may be difficult to selectively form them only in the display area DA. Accordingly, the functional layer FL, the common electrode E2, the capping layer CPL, and the encapsulation ENC may be positioned in the first peripheral area LA1. Edges of the substrate SB, the buffer layer BF, the functional layer FL, the common electrode E2, the capping layer CPL, the encapsulation layer ENC, the overcoat layer YOC, the inorganic insulating layer YILD, and/or the passivation layer YPVX may be aligned to define the opening area DTA or the through hole TH. The above-described first electronic module MD1, which may be a camera, may overlap the opening area DTA in the display device 1.

The functional layer FL, the common electrode E2, and the capping layer CPL may respectively have openings that overlap each other and collectively form an opening OP in the first peripheral area LA1, and may each include sections disconnected/spaced by the opening OP. The opening OP may penetrate the functional layer FL, the common electrode E2, and the capping layer CPL in the third direction z. The opening OP may surround the opening area DTA. In a plan view of the display device 1, the opening OP may have a ring shape. A plurality of openings OP may be formed in the layers FL, E2, and CPL. The openings OP may be spaced from each other may surround the opening area DTA in the plan view of the display device 1. The first inorganic layer EIL1 of the encapsulation layer ENC may be partially positioned in the opening OP. The first inorganic layer EIL1 may directly contact an upper surface of an organic layer OL (indicated in FIG. 7) exposed by the opening OP. The first inorganic layer EIL1 may directly contact a side surface of each of the functional layer FL, the common electrode E2, and the capping layer CPL defining the opening OP.

Without the opening(s) OP, the common electrode E2, and/or the capping layer CPL may form a moisture permeation path from the opening area DTA to the display area DA. In the first peripheral area LA1, the functional layer FL, the common electrode E2, and the capping layer CPL are cut (i.e., interrupted) by the opening(s) OP, so that the moisture permeation path may be blocked, and moisture from the opening area DTA may be prevented from penetrating into the display area DA through the functional layer FL, the common electrode E2, and/or the capping layer CPL. The opening OP may be formed by partially removing material layers of the functional layer FL, the common electrode E2, and the capping layer CPL.

One or more dams DM1 and DM2 may be positioned in the first peripheral area LA1. The first dam DM1 and the second dam DM2 may be spaced from each other. The second dam DM2 may surround the opening area DTA, and the first dam DM1 may surround the second dam DM2. The first dam DM1 and the second dam DM2 may be positioned on the buffer layer. The first dam DM1 and the second dam DM2 may have a multi-layered structure. The first dam DM1 and the second dam DM2 may control spreading of a material (e.g., a monomer) for forming the organic layer EOL of the encapsulation layer ENC. Accordingly, the organic layer EOL may not be positioned between the first dam DM1 and the opening area DTA or between the second dam DM2 and the opening area DTA. Beyond the organic layer EOL, the first inorganic layer EIL1 and the second inorganic layer EIL2 may directly contact each other. The functional layer FL, the common electrode E2, and the capping layer CPL may be positioned between the dams DM1 and DM2 and the encapsulation layer ENC.

Layers of the first dam DM1 and the second dam DM2 may be formed of the same material(s) as the first organic insulating layer VIA1, the second organic insulating layer VIA2, the pixel defining layer PDL, and/or the spacer SP in the same process. The first dam DM1 and/ or the second dam DM2 may include a first layer formed of the same material as the second organic insulating layer VIA2 in the same process, a second layer formed of the same material as the pixel defining layer PDL in the same process, and a third layer formed of the same material as the spacer SP in the same process. The first dam DM1 and/or the second dam DM2 may include a first layer formed of the same material as the first organic insulating layer VIA1 in the same process, a second layer formed of the same material as the pixel defining layer PDL in the same process, and a third layer formed of the same material as the spacer SP in the same process. The first dam DM1 and/or the second dam DM2 may include a first layer formed of the same material as the first organic insulating layer VIA1 in the same process, a second layer formed of the same material as the second organic insulating layer VIA2 in the same process, and a third layer formed of the same material as the pixel defining layer PDL in the same process.

The first dam DM1 and/or the second dam DM2 may include a first layer formed of the same material as the first organic insulating layer VIA1 or the second organic insulating layer VIA2 in the same process, and may include a second layer formed of the same material as the second organic insulating layer VIA2 or the pixel defining layer PDL in the same process. The first dam DM1 and/or the second dam DM2 may include a first layer formed of the same material as the pixel defining layer PDL in the same process, and a may include second layer formed of the same material as the spacer SP in the same process.

The first dam DM1 and/or the second dam DM2 may include a first layer formed of the same material as the first organic insulating layer VIA1 in the same process, a second layer formed of the same material as the second organic insulating layer VIA2 in the same process, a third layer formed of the same material as the pixel defining layer PDL in the same process, and a fourth layer formed of the same material as the spacer SP in the same process. Although two dams DM1 and DM2 are illustrated, more or fewer dams may be positioned in the peripheral area LA.

One or more cut portions CP1 to CP4 may be positioned in the first peripheral area LA1. The cut portions CP1 to CP4 may include a structure for forming openings OP in the functional layer FL, the common electrode E2, and the capping layer CPL, and/or may overlap the openings OP formed in the functional layer FL, the common electrode E2, and the capping layer CPL. The functional layer FL, the common electrode E2, and the capping layer CPL may cover the cut portions CP1 to CP4 except for areas overlapping the openings OP. The cut portions CP1 to CP4 may include a first cut portion CP1, a second cut portion CP2, a third cut portion CP3, and a fourth cut portion CP4 that are spaced from each other. The fourth cut portion CP4 may surround the opening area DTA, the third cut portion CP3 may surround the fourth cut portion CP4, the second cut portion CP2 may surround the third cut portion CP3, and the first cut portion CP1 may surround the second cut portion CP2. The first cut portion CP1 may be positioned between the second peripheral area LA2 and the first dam DM1. The second, third, and fourth cut portions CP2 to CP4 may be positioned between the second dam DM2 and the opening area DTA. The positions and number of the cut portions CP1, CP2, CP3, and CP4 may be different for different embodiments. For example, all cut portions may be positioned between the second dam DM2 and the opening area DTA, or the cut portion may be positioned between the first dam DM1 and the second dam DM2. The cut portions CP1, CP2, CP3, and CP4 may have substantially the same stacked structure, or may have different stacked structures.

The cut portions CP1 to CP4 may each include a semiconductor layer SL, a metal layer ML, and an organic layer OL between the semiconductor layer SL and the metal layer ML. The organic layer OL may completely cover the semiconductor layer SL. The metal layer ML may cover (opposite) side surfaces of the organic layer OL. The metal layer ML may include a portion directly contacting the buffer layer BF. The functional layer FL, the common electrode E2, and the capping layer CPL in which the opening OP is formed may be positioned on the metal layer ML.

An opening corresponding to the opening OP may be formed in the metal layer ML and may overlap an upper surface of the organic layer OL. The opening OP passing through the metal layer ML, the functional layer FL, the common electrode E2, and the capping layer CPL in the third direction z may be positioned on the organic layer OL. The opening OP may surround the opening area DTA. The opening OP may overlap each of the organic layer OL and the semiconductor layer SL. Before the encapsulation layer ENC is formed after the functional layer FL, the common electrode E2, and the capping layer CPL are formed, the opening OP passing through the metal layer ML, the functional layer FL, the common electrode E2, and the capping layer CPL are formed by partially removing the material layers of the functional layer FL, the common electrode E2, the capping layer CPL, and the metal layer ML by irradiating a laser to the metal layer ML. The laser may be irradiated toward the metal layer ML through the substrate SB. When the material layers of the metal layer ML, the functional layer FL, the common electrode E2, and the capping layer CPL are partially removed by the laser, if the laser is not properly configured, an edge portion of the metal layer ML adjacent to the removed portion (that is, a portion adjacent to the opening OP) and/or an edge portion of the common electrode E2 may have an irregular shape, i.e., a burr. The burr may extend in a direction away from a surface of the second organic layer OL2, and may substantially protrude in the third direction z or an oblique direction. The burr of the common electrode E2 may have a shape as if the edge of the common electrode E2 is rolled up.

In order to form the opening in the metal layer ML, a laser of high energy capable of vaporizing the material of the metal layer ML may be required. For example, when a laser having a high energy density of about 900 mJ/cm² or more is irradiated, the unwanted portion of the metal layer ML may be removed, but the substrate SB, the organic insulating layers VIA1 and VIA2 and other elements may be damaged (for example, carbonized) in the irradiated area, and thus reliability of the display device may deteriorate. Furthermore, due to a laser alignment error and/or an incorrect coverage of a laser beam, the laser may be irradiated to a wider area than the opening intended to be formed in the metal layer ML. In order to minimize damage potentially caused by the laser by maximizing the laser irradiation energy applied to the target area of the material layer of the metal layer ML while minimizing laser irradiation energy in other areas, the cut portions CP1 to CP4 may include resonant structures for amplifying the laser energy targeting the material layer of the metal layer ML.

The semiconductor layer SL, the metal layer ML, and the organic layer OL may form a laser resonant structure. The semiconductor layer SL may have a higher refractive index than the organic layer OL. For example, the refractive index of the semiconductor layer SL may be about 3.0 to about 4.0, and the refractive index of the organic layer OL may be about 1.5 to about 1.8. The organic layer OL may form a resonant cavity by providing a predetermined gap between the semiconductor layer SL and the metal layer ML. The organic layer OL may have thicknesses suitable for forming the resonant cavity, for example thicknesses in a range of about 1 µm to about 7 µm. The material layer of the metal layer ML may reflect laser light. Since the metal layer ML covers the side surfaces of the organic layer OL, the laser light may be prevented from being scattered outside the resonant structure. The semiconductor layer SL, the organic layer OL, and the metal layer ML may be referred to as a high refractive index layer (or a refractive layer having a relatively higher refractive index), a low refractive index layer (or a refractive layer having a relatively lower refractive index), and a reflective layer, respectively.

The semiconductor layer SL may be formed of the same material as the semiconductor layer AL in the same process. For example, the semiconductor layer SL may include polycrystalline silicon. The organic layer OL may include one or more organic layers that may be formed of the same material as the first organic insulating layer VIA1, the second organic insulating layer VIA2, the pixel defining layer PDL, or the spacer SP in the same process. For example, the organic layer OL may include a first organic layer OL1 formed of the same material as the first organic insulating layer VIA1 in the same process, and may include a second organic layer OL2 formed of the same material as the second organic insulating layer VIA2 in the same process. The metal layer ML may be part of a first data conductive layer, a second data conductive layer, or a pixel conductive layer. For example, the metal layer ML may be formed of the same material as the pixel electrode E1 in the same process. The metal layer ML may have a triple-layered structure of ITO-silver (Ag)-ITO. Because the semiconductor layer SL, the organic layer OL, and the metal layer ML may be formed of the same materials as elements formed in the display area DA in the same processes, no additional process step may be required to form the laser resonant structure.

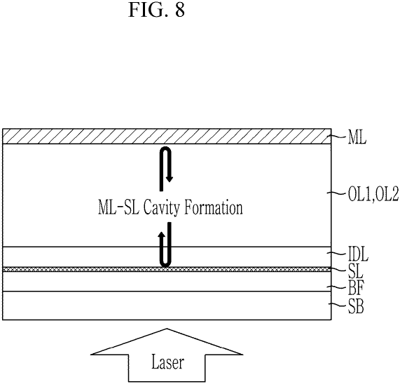

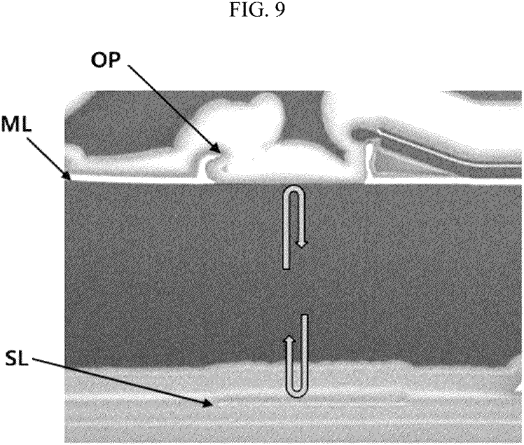

FIG. 8 illustrates a schematic view of a resonant structure according to an embodiment. FIG. 9 illustrates a photographed view of a processed cross-section of a pixel conductive layer using a resonant structure according to an embodiment.

Referring to FIG. 8, a laser (for example, an infrared laser) may be irradiated through the substrate SB toward the metal layer ML. The incident laser light may be reflected by the metal layer ML, and the reflected light may be reflected and scattered by the semiconductor layer SL. The reflected light and the scattered light may constructively interfere with each other, and a resonant phenomenon may occur. In order for light to cause constructive interference, it is necessary to form an appropriate resonant space, and at least one organic layer OL1 and OL2 having at least one thickness of the first organic insulating layer VIA1, the second organic insulating layer VIA2, the pixel defining layer PDL, and/or the spacer SP may provide a space suitable for forming a resonant cavity. An inorganic insulating layer such as the interlayer insulating layer ILD may be positioned between the semiconductor layer SL and the organic insulating layers OL1 and OL2. Since the inorganic insulating layer has a small refractive index (for example, about 1.4), and since the inorganic insulating layer is considerably thinner than the organic insulating layers OL1 and OL2, the inorganic insulating layer may not significantly affect the resonance structure.

FIG. 9 is a projection electron micrograph showing that the opening OP was formed in the metal layer ML when the stacked structure shown in FIG. 8 was irradiated with a laser having an energy density of about 100 mJ/cm² in the resonance structure formed by the semiconductor layer SL, the organic insulating layer VIA, and the metal layer ML. Even when a laser having a low energy density was irradiated through the substrate SB (shown in FIG. 8), a hot spot sufficient to vaporize the metal layer ML was formed through the resonance, so that the opening OP was formed in the metal layer ML. Although the formation of the opening OP was possible using a laser having an energy density of about 800 mJ/cm² in the absence of the resonant structure, the energy density of the laser may be lowered to about ⅛ by the resonant structure. Since laser power may be reduced when the opening OP, defects (such as carbonization) in the substrate SB, the organic insulating layer, and other elements may be prevented.

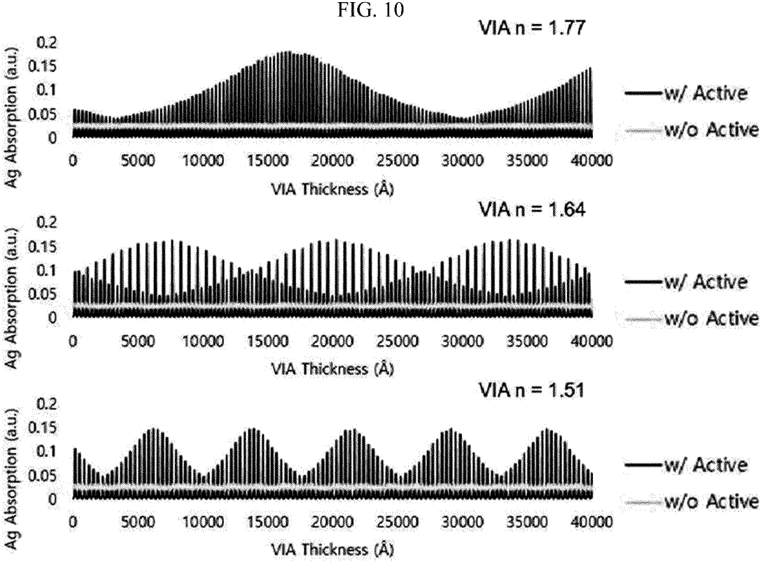

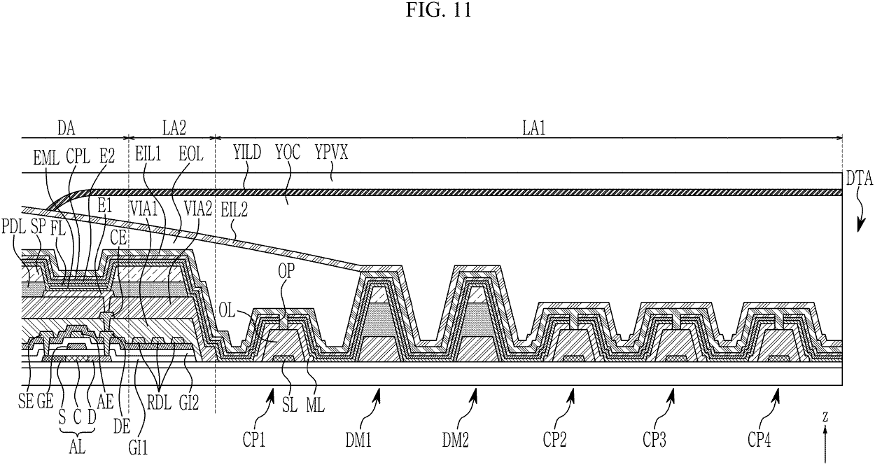

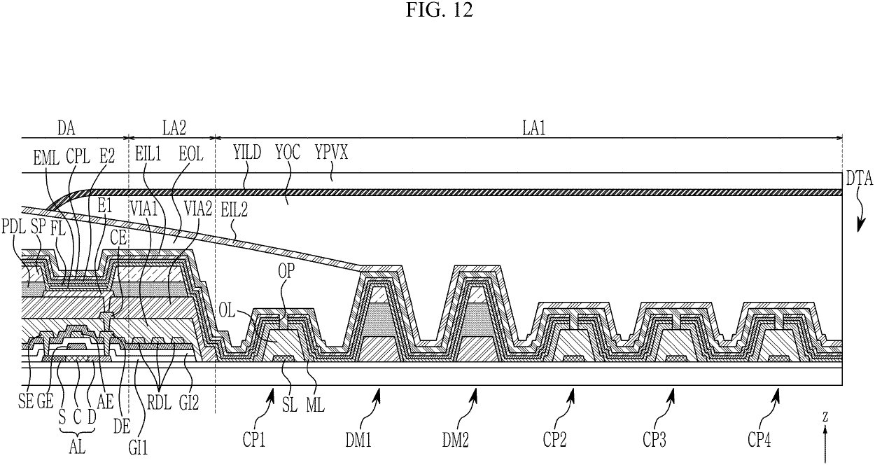

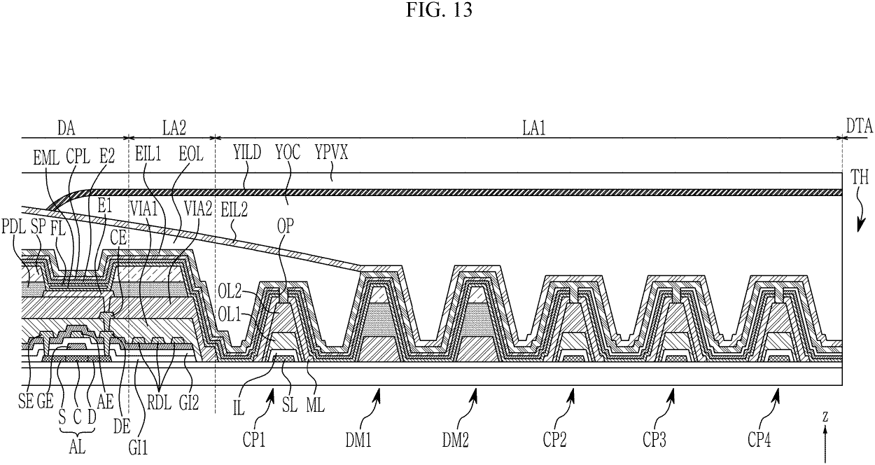

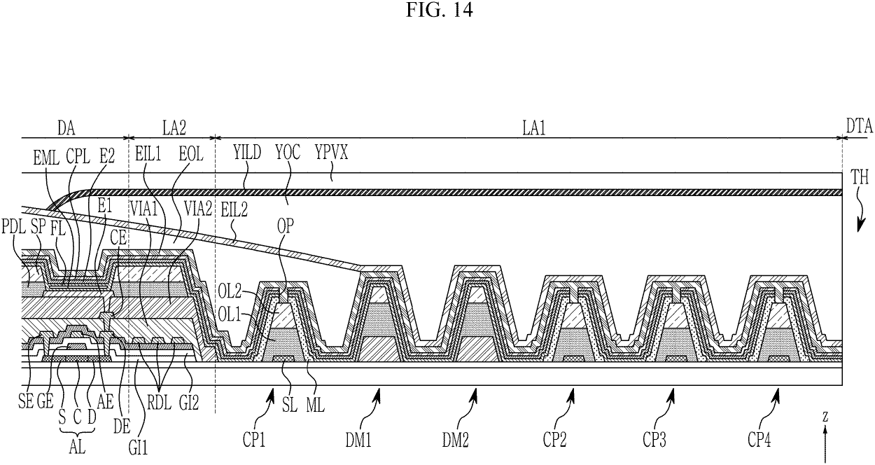

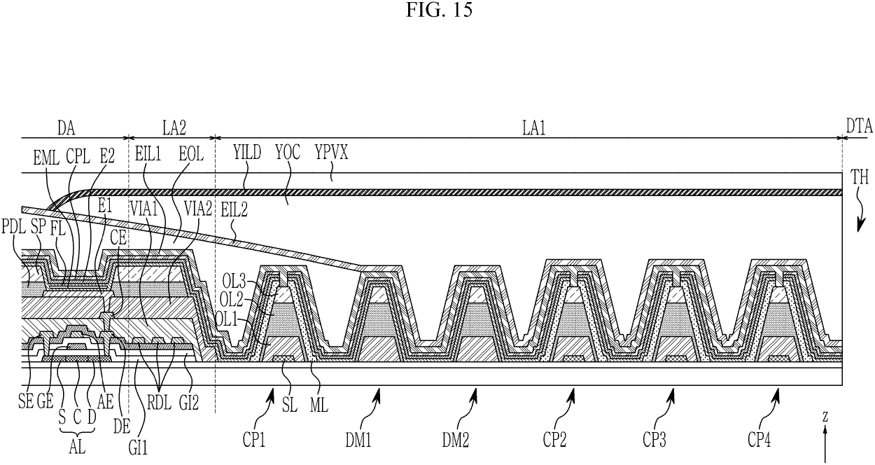

FIG. 10 illustrates graphs of laser energy amplification simulation results according to presence or absence of a semiconductor layer, a refractive index of an organic layer, and a thickness of the organic layer.

In the graphs, black bars indicate absorption of a metal layer when the metal layer was irradiated with a laser and formed a resonant structure with a semiconductor layer (or active layer), and gray bars indicate absorption of a metal layer when the metal layer was irradiated with a laser and did not form a resonance structure with a semiconductor layer. A polycrystalline silicon layer and a silver (Ag) layer were used for the semiconductor layer and the metal layer, respectively, and a laser having a wavelength of 1054 nm was used. The first graph shows absorbance according to a thickness of an organic layer when a resonant cavity is formed by the organic layer having a refractive index of 1.77 between the semiconductor layer and the metal layer. The absorbance periodically varied as the thickness of the organic layer increased, and at a thickness of about 1.7 µm, a maximum amplification effect was about 6.3 times greater than that of a structure without the semiconductor layer. The second and third graphs show that as the refractive index of the organic layer decreased, the absorbance period and the maximum absorbance decreased according to the thickness of the organic layer. Although there was a difference in the amplification effect according to the refractive index and thickness of the organic layer, the organic layer for forming the resonant structure capable of attaining the absorption amplification effect may be obtained using the organic insulating layers formed in the display area DA with no additional process.

Each of FIG. 11, FIG. 12, FIG. 13, FIG. 14, and FIG. 15 illustrates a cross-sectional view of a peripheral area in a display panel according to an embodiment.

Referring to FIG. 11, the cut portions CP1 to CP4 may include a semiconductor layer SL, an organic layer OL, and a metal layer ML sequentially stacked on the buffer layer BF. The organic layer OL may be a single layer. The organic layer OL may be formed of the same material as the second organic insulating layer VIA2 in the same process. The semiconductor layer SL may be formed of the same material as the semiconductor layer AL in the same process. The metal layer ML may be part of a pixel conductive layer.

Referring to FIG. 12, the organic layer OL may be a single layer and may be formed of the same material as the first organic insulating layer VIA1 in the same process. The metal layer ML may be part of the second data conductive layer and may be formed of the same material as the connecting member CE in the same process. The metal layer ML may be part of a pixel conductive layer.

Referring to FIG. 13, the cut portions CP1 to CP4 may include a semiconductor layer inorganic SL, an inorganic layer IL, an organic layer OL (e.g., OL1 and OL2), and a metal layer ML sequentially stacked on the buffer layer BF. The inorganic layer IL is positioned between the semiconductor layer SL and the organic layer OL. The inorganic layer IL may include the same material as at least one of the first gate insulating layer GI1, the second gate insulating layer GI2, and the interlayer insulating layer ILD. Since the inorganic layer IL may be formed thinner than the organic layer OL, it may be advantageous to finely control the resonant thickness/space between the semiconductor layer SL and the metal layer ML.

Referring to FIG. 14, the cut portions CP1 to CP4 may include a semiconductor layer SL, an organic layer OL, and a metal layer ML sequentially stacked on the buffer layer BF, wherein the organic layer OL may include a first organic layer OL1 and a second organic layer OL2. The first organic layer OL1 may be formed of the same material as the pixel defining layer PDL in the same process, and the second organic layer OL2 may be formed of the same material as the spacer SP in the same process. A reflective metal layer may not be positioned between the spacer SP and the encapsulation layer ENC in the display area DA. Accordingly, the metal layer ML may be formed through a separate process rather than a process for forming elements of the display area DA.

Referring to FIG. 15, the organic layer OL of the cut portions CP1 to CP4 may include a first organic layer OL1, a second organic layer OL2, and a third organic layer OL3. The first organic layer OL1 may be formed of the same material as the second organic insulating layer VIA2 in the same process, the second organic layer OL2 may be formed of the same material as the pixel defining layer PDL in the same process, and the third organic layer OL3 may be formed of the same material as the spacer SP in the same process. The first organic layer OL1 may be formed of the same material as the first organic insulating layer VIA1 in the same process, the second organic layer OL2 may be formed of the same material as the pixel defining layer PDL in the same process, and the third organic layer OL3 may be formed of the same material as the spacer SP in the same process. The metal layer ML may be formed through a separate process rather than a process for forming elements of the display area DA. The cut portions CP1 to CP4 may surround the opening area DTA, may be disposed between the display area DA and the opening area DTA, may have a predetermined height, and may function as dams DM.

The cut portions CP1 to CP4 may have the same structure, or may have different structures. The inorganic layer IL described with reference to FIG. 13 may be included in the cut portions CP1 to CP4 described with reference to one or more of other figures.

While examples of embodiments have been described, practical embodiments are not limited to the described embodiments. Practical embodiments cover various modifications and equivalent arrangements within the scope of the appended claims.

What is claimed is:

1. A display device comprising:
a substrate including an opening area, a peripheral area surrounding the opening area, and a display area surrounding the peripheral area;
a pixel electrode overlapping the display area;
a common electrode overlapping the pixel electrode;
an intermediate layer disposed between the pixel electrode and the common electrode and including a light emitting layer and a functional layer;
a semiconductor layer overlapping the peripheral area and spaced from the display area;
a metal layer overlapping the semiconductor layer; and
an organic layer disposed between the semiconductor layer and the metal layer,
wherein the common electrode, the functional layer, and the metal layer respectively have a first opening, a second opening, and a third opening overlapping each other and overlapping the semiconductor layer.

2. The display device of claim 1, further comprising
an encapsulation layer overlapping the common electrode and including an inorganic layer,
wherein the inorganic layer directly contacts the organic layer through the first opening, the second opening, and the third opening.

3. The display device of claim 2, further comprising
a capping layer disposed between the common electrode and the encapsulation layer,
wherein the capping layer has a fourth opening overlapping at least one of the first opening, the second opening, and the third opening.

4. The display device of claim 1, wherein at least one of the first opening, the second opening, and the third opening surrounds the opening area.

5. The display device of claim 4, wherein the third opening is ring-shaped.

6. The display device of claim 1, wherein the metal layer covers a side surface of the organic layer.

7. The display device of claim 6, further comprising
a buffer layer disposed between the substrate and the semiconductor layer,
wherein the metal layer directly contacts the buffer layer.

8. The display device of claim 1, wherein a material of the metal layer is identical to a material of the pixel electrode.

9. The display device of claim 1, wherein thicknesses of the organic layer are in a range of 1 µm to 7 µm.

10. The display device of claim 1, further comprising
a first organic insulating layer, a second organic insulating layer, a pixel defining layer, and a spacer sequentially stacked on the display area,
wherein the organic layer includes a layer formed of a same material as at least one of the first organic insulating layer, the second organic insulating layer, the pixel defining layer, and the spacer.

11. The display device of claim 1, wherein the organic layer includes a first organic layer and a second organic layer overlapping the first organic layer.

12. The display device of claim 1, further comprising
an inorganic layer disposed between the semiconductor layer and the organic layer.

13. The display device of claim 1, wherein the substrate includes a through hole passing through the opening area.

14. The display device of claim 1, wherein the functional layer includes at least one of a hole injection layer, a hole transport layer, an electron transport layer, and an electron injection layer.

15. The display device of claim 1, further comprising
a dam overlapping the peripheral area and surrounding the opening area,
wherein the third opening is disposed between the display area and the dam or disposed between the dam and the opening area.

16. A display device comprising:
a substrate that includes a display area, an opening area including a through hole, and a peripheral area between the display area and the through hole;
a light emitting diode overlapping the display area and including a pixel electrode, a portion of an intermediate layer, and a portion of a common electrode; and
a cut structure overlapping the peripheral area, spaced from the display area, and including a first refractive layer, a second refractive layer, and a reflective layer,
wherein a refractive index of the first refractive layer is higher than a refractive index of the second refractive area,
wherein the intermediate layer and the common electrode respectively have a first opening and a second opening overlapping each other and overlapping the cut structure.

17. The display device of claim 16, wherein at least one of the first opening and the second opening surrounds the through hole.

18. The display device of claim 16,
wherein the intermediate layer includes a light emitting layer and a functional layer,
wherein the functional layer includes at least one of a hole injection layer, a hole transport layer, an electron transport layer, and an electron injection layer, and
wherein the functional layer overlaps the peripheral area.

19. The display device of claim 16, further comprising
an encapsulation layer covering the light emitting diode and including an inorganic layer,
wherein the inorganic layer directly contacts the second refractive layer through the first opening and the second opening.

20. The display device of claim 16,
wherein the second refractive layer overlaps the first refractive layer,
wherein the first refractive layer is disposed between the second refractive layer and the substrate, and
wherein the reflective layer covers a side surface of the second refractive layer.
